(19) United States
(12) Patent Application Publication
(10) Pub. No.: US 2005/0258869 A1
(43) Pub. Date: Nov. 24, 2005

(54) Balanced line output stage circuit providing reduced electromagnetic interference

(75) Inventor: Erkka Juhani Sointula, San Diego, CA (US)

Correspondence Address: HARRINGTON & SMITH, LLP, 4 RESEARCH DRIVE, SHELTON, CT, 06484-6212, US

(73) Assignee: Nokia Corporation, Espoo (FI)

(21) Appl. No.: 10/852,635

(22) Filed: May 24, 2004

(51) Int. Cl. H03K 19/094

(52) U.S. Cl. 326/86

(57) ABSTRACT

A differential line output cell (10) contains a current source (M1,M2) having an output; a plurality of switches (S1,S2,S3,S4) arranged in a bridge configuration and coupled between the output of the current source and ground, and a capacitance (C) coupled between the output of the current source and ground. In a preferred embodiment the differential line output cell, including the capacitance, are fabricated as part of an integrated circuit, such as an RF IC (20) or a BB IC (30) of a mobile station (50). The capacitance has a value selected to charge a capacitance associated with output lines (5A,5B), which in the preferred embodiment are a pair of PWB traces.

### TECHNICAL FIELD

This invention relates generally to circuitry for driving electrical conductors, such as wires, cables and printed circuit wiring and, more specifically, relates to balanced output line driver circuits suitable for use in, as an example, an interface circuit of a battery powered mobile communications device, such as a cellular telephone.

### BACKGROUND

Modern cellular telephones and other types of wireless communications devices use a number of different digital interfaces between integrated circuits (ICs), modules and accessories, and send waveforms having voltage and/or current transitions over printed wiring board (PWB) traces and through discrete wires, all of which can be referred to collectively as conductors. Depending on the possibly numerous interface parameters, such as rise time and transmission speed, these conductors can transmit or receive electromagnetic interference (EMI) via electromagnetic coupling or conductive coupling within the device and also external to the device.

Due to these developments the radio frequency/base band (RF/BB) interface is changing from one having an analog-type, low level EMI to a higher level digital-type EMI that results from the current spikes generated by the rapid turning on and off of large numbers of IC transistors. In general, the RF IC is a most sensitive part of the device, and is thus can be the most susceptible to the higher levels of digital-type EMI.

One known type of balanced interface circuit addresses the electromagnetic coupling from the interface output bonding wires to other bonding wires. However, the known type of balanced interface circuit does not adequately address the problem of conductive coupling caused by the interface circuit power supply and ground currents, without the use of large external filtering components and with a minimum amount of current consumption.

Examples of conventional output buffer driver designs are shown in U.S. Pat. Nos. 6,469,566 B2, “Pre-Charging Circuit of an Output Buffer”, by S. Nicosia and U.S. Pat. No. 5,420,525, “Low Switching Noise Output Buffer”, by F. Maloberti et al., and in U.S. Published patent application Ser. No.: 2003/0080781 A1, “Low-Noise Output Buffer”, by G. Curatolo et al.

Also representative of conventional interface circuits is a type known as a low voltage differential signaling (LVDS) driver, as described in the following publications: AN-115, “DS92LV010A Bus LVDS Transceiver Ushers in a New Era of High-Performance Backplane Design”, John Goldie, July 1998 (National Semiconductor Application Note); “BusLVDS Expands Applications for Low Voltage Differential Signaling (LVDS)”, Stephen Kempainen, DesignCon 2000 (2000); and “Low-Voltage Differential Signaling (LVDS), Part 1”, Stephen Kempainen, Insight, Volume 5, Issue 2 (2000). These devices are capable of operation at data rates in excess of 100 Mbits/sec, and with a power supply voltage of less than 5 VDC. The differential signals are used because of their immunity to common mode noise.

FIG. 1 shows a prior art LVDS physical layer circuit as depicted in Slide 5 of the DesignCon 2000 document referred to above. In the current steering differential driver 1 a current source 2 limits the output to about 3 mA, and a switch box 3 steers the current through a termination resistance 4. The differential driver 1 produces an odd-mode transmission, meaning that equal and opposite currents flow in the transmission lines 5A, 5B. As the current returns within the wire pair the current loop area is small, reducing the amount of generated EMI. The current source 2 limits spike currents that could occur during transitions. The differential receiver 6 is a high impedance device capable of detecting as a little as 20 mV differential signals and amplifying these signals into standard logic levels.

Without the use of large external filtering components, the prior art differential driver circuit 1 does not overcome the above-noted problem of conductive coupling caused by the interface circuit power supply and ground currents. Such external filtering components can take the form of capacitors connected between the supply voltage pins (Vdd) and ground.

### SUMMARY OF THE PREFERRED EMBODIMENTS

The foregoing and other problems are overcome, and other advantages are realized, in accordance with the presently preferred embodiments of these teachings.

In one aspect this invention provides a differential line output cell that contains a current source having an output; a plurality of switches arranged in a bridge configuration and coupled between the output of the current source and ground, where the plurality of switches are arranged for being coupled to a first output line and to a second output line for driving the output lines so as to drive, at a first time, the current from the current source out of the first output line and into the second output line to ground, and at a second time, the current from the current source out of the second output line and into the first output line to ground. In accordance with the invention the differential line output cell further includes a capacitance coupled between the output of the current source and ground. In a presently preferred embodiment of the invention the differential line output cell, including the capacitance, are fabricated as part of an integrated circuit, such as an RF IC or a BB IC of a mobile station. The capacitance has a value selected to charge a capacitance associated with the output lines, which in the preferred embodiment are a pair of PWB traces.

### BRIEF DESCRIPTION OF THE DRAWINGS

The foregoing and other aspects of these teachings are made more evident in the following Detailed Description of the Preferred Embodiments, when read in conjunction with the attached Drawing Figures, wherein:

FIG. 1 is schematic diagram of a convention differential driver circuit;

FIG. 2 is a schematic diagram of a differential driver circuit in accordance with this invention;

FIG. 3 is a simplified equivalent circuit for the embodiment of FIG. 2; and

FIG. 4 shows the use of the differential driver circuit of FIG. 2 between an RF IC and a BB IC.

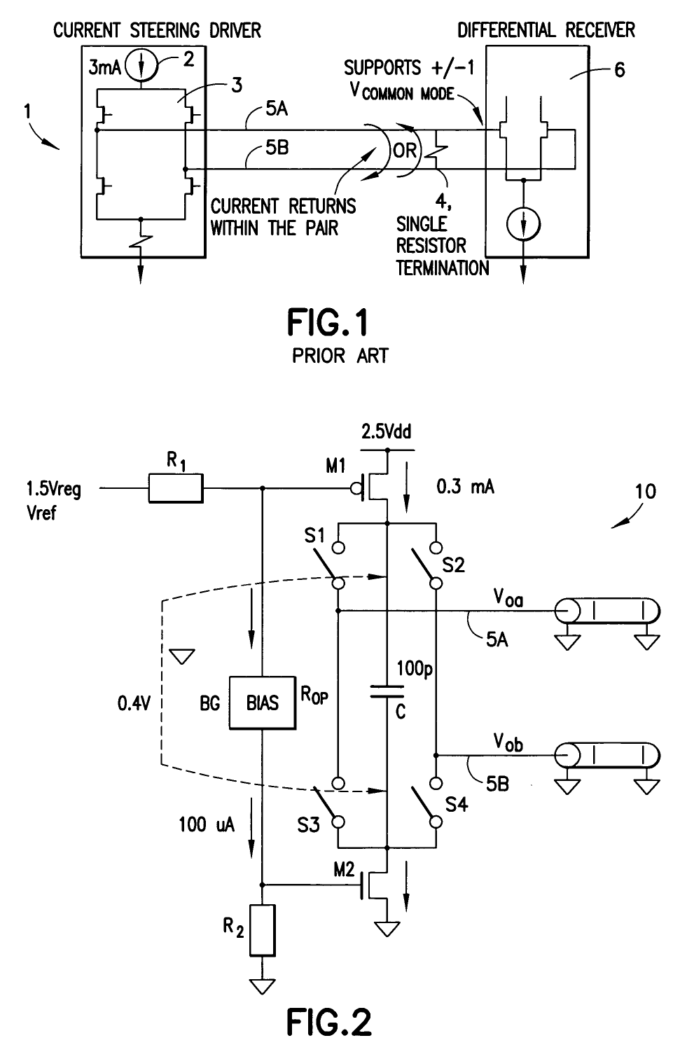

### DETAILED DESCRIPTION OF THE PREFERRED EMBODIMENTS

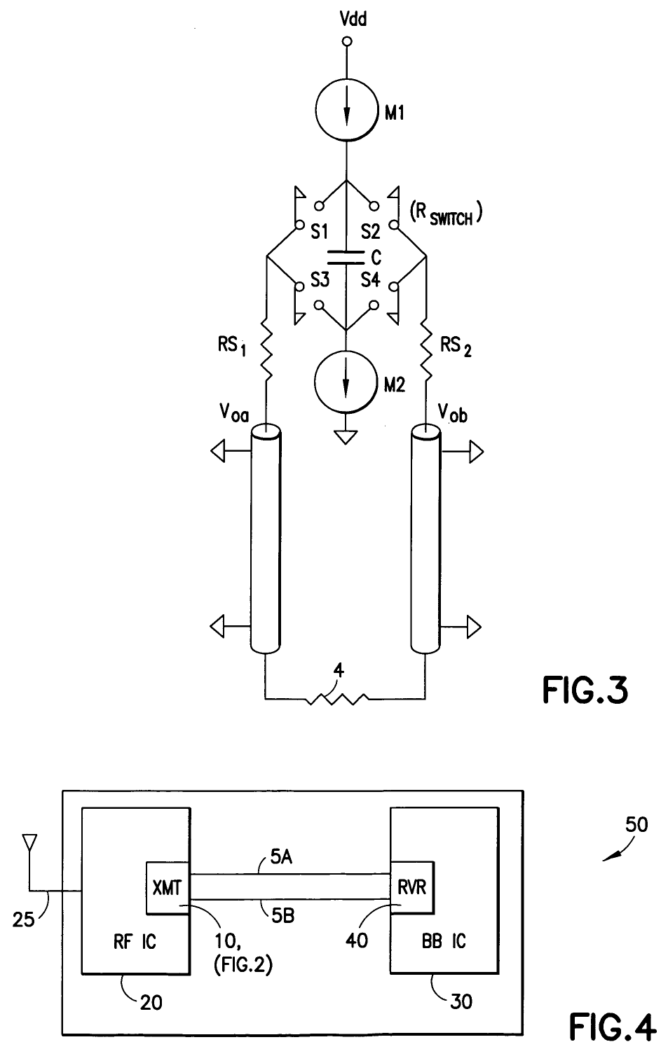

Reference is made to FIG. 2 for showing a circuit diagram of a differential driver circuit, also referred to herein as a differential line output cell 10, in accordance with this invention. The differential line output cell 10 comprises bias network resistors R1 and R2 that function with a bias generator BG for biasing constant current source transistors M1 (P-channel MOSFET) and M2 (N-channel MOSFET) that are coupled between Vdd (e.g., 2.5 VDC) and ground, and a plurality of switches S1, S2, S3 and S4, preferably implemented as FET switches arranged in a bridge configuration. Referring also to FIG. 3, in operation the switches S1, S4 are closed and S2, S3 opened to drive the constant current (e.g., 0.3 mA) sourced by M1 in a first direction out through line 5A and back to ground, via M2, through line 5B. Switches S1, S4 are then opened and switches S2, S3 closed to drive current in the opposite direction out through line 5B and back in to ground, via M2, through line 5A.

In accordance with this invention a capacitance C, such as a 100 picofarad (pF) capacitance, is coupled in series with M1 and M2, and in parallel with switch pairs S1, S3 and S2, S4. The capacitance C functions as an output voltage source to the line, and all fast transient currents of the line are drawn from C, thereby minimizing the supply and ground current transients. A particular advantage of this approach is that C can be physically located very close to the output lines 5A and 5B, and much closer than a conventional external discrete filter capacitance could be. This feature in and of itself significantly reduces generated EMI, as well as received EMI, as the line lengths between the filter capacitance and the output lines 5A, 5B are significantly reduced, and thus so is the ability of the lines to radiate and receive EMI. The static current consumption of the differential line output cell 10 is also minimized by the presence of C. Using current RF IC semiconductor IC processes, a 100 pF capacitor requires a circuit area of only 0.02 mm².

For the exemplary and non-limiting illustrated values of Vdd=2.5V and Vref=1.5V, the bias current through R2 is 100 microamps, the constant current source output current is 0.3 mA, and the voltage potential across C is about 0.4V.

In the equivalent circuit depicted in FIG. 3 the optional resistor termination 4 is also shown. FIG. 3 shows clearly that C is actually coupled in series with the current source comprised of M1 and M2, and more specifically is coupled to the output of the current source transistor M1. As can be appreciated, this type of coupling would not normally be possible if C were instead coupled from the Vdd pin to ground. In this (conventional) case C would be in parallel with the current source, not in series with it as shown.

In a preferred embodiment the output buffer impedance is matched to the line impedance which, if a stripline or coaxial cable is used, is nominally about 50 Ohms. RS₁ and RS₂ are resistances in series with the lines, having values of about 50 Ohms. If the switch resistance R_{switch} is not ideal (zero) and is near to 50 Ohms then RS₁ and RS₂ may be dispensed with. If the switch resistance R_{switch} is greater than zero but less than 50 Ohms, then RS₁ and RS₂ can be added to make up the difference, such that R_{switch}=RS=50 Ohm=buffer output impedance.

M1 and M2 together with C function as a low pass and peak current filter. Peak currents are preferably not drawn from Vdd, but are instead drawn from C, which is preferably placed close to the line input. This is distinguished from the prior art, where M1 and M2 may be considered to be short circuited, such that large transient currents are drawn from Vdd (which has a large ground loop).

A further advantage is obtained for digital signals where the line length is<<c/(max.bitrate/2), which is typically the case in the applications of most interest to this invention, such as in mobile phones and handheld terminals. In this case the value of resistor 4 can be high, resulting in low static current consumption. Under dynamic conditions the current drawn is only that required to load the line capacitance (typically a few picofarads) during state changes. However, this invention can also be used with longer line lengths, such as when it is desired to connect to an accessory device, as a reduced EMI advantage is still obtained. The use of shorter lines is preferred, as with longer line lengths the multiple reflections can sum, leading to overloading the output stage. The current consumption advantages as compared to the unterminated line case will be, at least partially, lost.

In general, the use of the differential line output cell 10 provides for a low level of supply and ground current ripple, a low static current consumption (in particular if the termination resistance 4 is not used), and furthermore reduces or substantially eliminates the need for supply voltage filtering through the use of external capacitors or other filtering components.

The differential line output cell 10 is particularly well suited for those applications where the distance between driver and receiver is small, such as in mobile station applications where the ICs are connected together with traces on a PWB, as shown in FIG. 4.

In general, the line length divided by the frequency is equal to the wavelength, where the wavelength of the signal in the line is much longer than length of the line. If the line length is of same order or longer than wavelength then the line is preferably terminated at the receiver input. In a typical case the line end (i.e., the receiver input) is terminated with the same impedance as the source (differential line output cell 10) output to prevent reflections (VSWR). In practice the input impedance is of the order of greater than 100 k Ohm, and the source impedance is typically of the order of 100 Ohm. The interface is preferably source terminated, if the switch impedance is low, and there may be serial resistors in the line input to set the impedance. The line (PWB trace) parasitic capacitance is typically of the order of 3 pF. Because the receiver input impedance is very high the capacitor C in the switch bridge (S1-S4) needs only to charge the 3 pF equivalent capacitance of the line (5A, 5B). This is the primary reason why only a small capacitor (e.g., 100 pF) is needed at the source in the driver 10, and thus why it is possible to integrate C on the IC. The use of small switching transistors for S1-S4 is also rendered possible because of the small magnitudes of the currents, and the absence of reflections from the receiver.

The current consumption can be decreased if the resistor termination (R4) at the receiver is not used. The differential line output cell 10 can also be used with the terminated receiver, as shown in FIG. 4, to improve EMI, but at the expense of increased current consumption.

FIG. 4 shows the use of the differential driver circuit transmitter (XMT), the differential line output cell 10 of FIGS. 2 and 3, over PWB trace lines 5A, 5B between an RF IC 20 and a BB IC 30, where the BB IC 30 includes the receiver (RVR) 40. Alternatively, the BB IC 30 could contain the differential line output cell 10 and the RF IC 20 the RVR 40. In a presently preferred embodiment of this invention the RF IC 20 and the BB IC 30 are contained within and are components of a mobile station 50, such as a cellular telephone or other type of wireless communications and/or wireless gaming and/or wireless Internet appliance device. In this case the RF IC 20 will be coupled to at least one antenna 25.

The foregoing description has provided by way of exemplary and non-limiting examples a full and informative description of the best method and apparatus presently contemplated by the inventors for carrying out the invention. However, various modifications and adaptations may become apparent to those skilled in the relevant arts in view of the foregoing description, when read in conjunction with the accompanying drawings and the appended claims. As but some examples, the use of other similar or equivalent component, voltage and current values may be attempted by those skilled in the art. However, all such and similar modifications of the teachings of this invention will still fall within the scope of this invention.

Furthermore, some of the features of the present invention could be used to advantage without the corresponding use of other features. As such, the foregoing description should be considered as merely illustrative of the principles of the present invention, and not in limitation thereof.

1. A differential line output cell, comprising:
a current source having an output;
a plurality of switches arranged in a bridge configuration and coupled between the output of said current source and ground, said plurality of switches for being coupled to a first output line and to a second output line for driving the output lines so as to drive, at a first time, the current from said current source out of the first output line and into the second output line to ground, and at a second time, the current from said current source out of the second output line and into the first output line to ground; and
a capacitance coupled between the output of said current source and ground.

2. A differential line output cell as in claim 1, where said differential line output cell, including said capacitance, are fabricated as part of an integrated circuit.

3. A differential line output cell as in claim 1, where said capacitance has a value selected to charge a capacitance associated with said output lines.

4. A differential line output cell as in claim 1, where said current source comprises a first transistor coupled between a supply voltage and a top of the bridge configuration, a second transistor coupled between ground and a bottom of the bridge configuration, and a bias network for biasing the first and second transistors to provide a constant current output.

5. A differential line output cell as in claim 2, where said integrated circuit is comprised of a radio frequency integrated circuit.

6. A differential line output cell as in claim 2, where said integrated circuit is comprised of a base band integrated circuit.

7. A differential line output cell as in claim 3, where said capacitance has a value of about 100 pF.

8. A differential line output cell as in claim 2, where said integrated circuit forms a part of a mobile station.

9. A method to reduce electromagnetic interference, comprising:
providing an integrated circuit that comprises a differential line output cell containing a current source having an output, a plurality of switches arranged in a bridge configuration and coupled between the output of said current source and ground, said plurality of switches for being coupled to a first output line and to a second output line of said integrated circuit for driving the output lines;
driving, at a first time, the current from said current source out of the first output line and into the second output line to ground, and at a second time, the current from said current source out of the second output line and into the first output line to ground; and
while driving the current, charging a capacitance associated with said output lines with a capacitance of said differential line output cell that is coupled between the output of said current source and ground.

10. A method as in claim 9, where said current source comprises a first transistor coupled between a supply voltage and a top of the bridge configuration, a second transistor coupled between ground and a bottom of the bridge configuration, further comprising biasing the first and second transistors to provide a constant current output.

11. A method as in claim 9, where said integrated circuit is comprised of a radio frequency integrated circuit.

12. A method as in claim 9, where said integrated circuit is comprised of a base band integrated circuit.

13. A method as in claim 9, where said integrated circuit forms a part of a mobile station.

14. A method as in claim 9, where said capacitance has a value of about 100 pF.

15. A mobile station, comprising a radio frequency integrated circuit (RF IC) coupled to a base band integrated circuit (BB IC) via printed wiring board (PWB) traces, where at least one of said RF IC and said BB IC comprises a differential line output transmitter cell coupled to a differential line input receiver cell in the other one of said RF IC and BB IC through a pair of said PWB traces, said differential line output transmitter cell comprising a current source having an output, a plurality of switches arranged in a bridge configuration and coupled between the output of said current source and ground, said plurality of switches for being coupled to a first output line and to a second output line for driving the output lines so as to drive, at a first time, the current from said current source out of the first output line and into the second output line to ground, and at a second time, the current from said current source out of the second output line and into the first output line to ground; and a capacitance coupled between the output of said current source and ground.

16. A mobile station as in claim 15, where said capacitance has a value selected to charge a capacitance associated with said pair of PWB traces.

17. A mobile station as in claim 15, where said current source comprises a first transistor coupled between a supply voltage and a top of the bridge configuration, a second transistor coupled between ground and a bottom of the bridge configuration, and a bias network for biasing the first and second transistors to provide a constant current output.

18. A mobile station as in claim 15, where said capacitance has a value of about 100 pF.

19. A differential line output cell, comprising:
a current source having an output node;
a plurality of switches arranged in a bridge configuration and coupled between the output node of said current source and ground, said plurality of switches for being coupled to a first output line and to a second output line for driving the output lines so as to drive, at a first time, the current from said current source out of the first output line and into the second output line to ground, and at a second time, the current from said current source out of the second output line and into the first output line to ground; and
a capacitance extending from the output node of said current source to ground, the capacitance being charged during both the first and second times.

20. A differential line output cell as in claim 19, wherein the bridge configuration has two branches, the capacitance being in parallel with both of the two branches, the first output line being electrically connected to a node between two switches on one of the two branches of the bridge configuration, the second output line being electrically connected to a node between two switches on an other of the two branches of the bridge configuration.
